(19) United States
(12) Patent Application Publication
(10) Pub. No.: US 2006/0205192 A1
(43) Pub. Date: Sep. 14, 2006

(54) Shallow-junction fabrication in semiconductor devices via plasma implantation and deposition

(75) Inventors: Steven R. Walther, Andover, MA (US); Sandeep Mehta, Beverly, MA (US); Ukyo Jeong, Andover, MA (US); Naushad K. Variam, Marblehead, MA (US)

Correspondence Address: Mark A. Superko, Esq.;Varian Semiconductor Equipment Associates, Inc., 35 Dory Road, Gloucester, MA, 01930, US

(73) Assignee: Varian Semiconductor Equipment Associates, Inc., Gloucester, MA (US)

(21) Appl. No.: 11/076,695

(22) Filed: Mar. 9, 2005

(51) Int. Cl. H01L 21/425

(52) U.S. Cl. 438/513; 438/514; 438/528

(57) ABSTRACT

A method for fabricating a semiconductor-based device includes disposing a substrate in a process chamber of a process tool, plasma implanting a dopant species from a plasma into a portion of the substrate in the process chamber, and plasma depositing a diffusion barrier on the implanted portion of the substrate prior to removing the at least one substrate from the process tool. The diffusion barrier can be deposited in the same chamber as that used for dopant implantation or a different chamber of the process tool.

### FIELD OF THE INVENTION

The invention relates to semiconductor-based devices, and, in particular, to semiconductor-based devices having shallow junctions, and methods and tools for fabricating such devices.

### BACKGROUND OF THE INVENTION

The evolution of integrated circuit (IC) design and manufacturing methods continues to provide metal-oxide-semiconductor field-effect transistors (MOSFETs) and other devices having ever faster switching and lower power consumption. These devices can have shorter channel lengths, lower power-supply and threshold voltages, and thinner gate oxides.

These devices can include shallow junctions, such as shallow source and drain junctions in a MOSFET, to reduce short-channel effects. Notably, the Semiconductor Industry Association (SIA) roadmap for ultra-large-scale-integration (ULSI) technology has included ever more aggressive source and drain junction depths, for example: for 0.25 μm (micrometer) technology, junction depths of 60-100 nm (nanometer) (1998); for 0.18 μm technology, junction depths of 40-60 nm (2001); and for 0.12 μm technology, junction depths of 20-40 nm (2007.)

To achieve the required control over dopant location, shallow junctions are commonly formed from ion implanted dopants. Although ion implantation can provide a well controlled dose of dopant, subsequent thermal-related processing can alter the concentration and spatial distribution of the implanted dopant.

For example, native-oxide formation after implantation can consume implanted dopant residing near a wafer surface. The loss of dopant due to oxide formation can be particularly significant for shallow junction formation because the dopant must be implanted close to the substrate surface to produce the shallow junction. Native oxide growth can consume, for example, about 2 nm of the surface of a silicon substrate.

Moreover, activation anneals can cause loss of implanted dopant. During an activation anneal, dopant can diffuse through a surface of a native oxide layer, and thus be lost. Further, oxygen in an ambient gas can lead to oxygen-enhanced diffusion (OED) of dopant, causing an increase in junction depth.

Boron is a particularly critical dopant, and can be more difficult to control during fabrication than other dopants. Boron is implanted at relatively low energies due to its low atomic weight, and is a relatively fast diffuser.

### SUMMARY OF THE INVENTION

One embodiment of the invention arises from the realization that loss of dopant related to diffusion effects can be reduced by both implanting junction dopant and depositing a diffusion barrier in a single plasma-processing fabrication tool. The diffusion barrier can block formation of native oxide after implantation and/or can reduce loss of dopant upon subsequent annealing. Both implant and diffusion barrier deposition can occur in the same chamber, or in different chambers, of the plasma-processing tool, such as a plasma implantation tool, without exposing the substrate to an ambient atmosphere by removing the substrate from the plasma-processing tool. Thus, growth of native oxide prior to deposition of the diffusion barrier can be avoided.

Suitable plasmas can be formed from one or more materials, which can provide one or more implant species and/or one or more species to contribute to deposition of a barrier layer. For example, an implant material can be a dopant gas, and a barrier material can be derived, at least in part, from species included in an implant material. In some embodiments, a barrier layer is deposited after a dopant is implanted.

According to one aspect of the invention, a method is provided for fabricating a semiconductor-based device. The method includes disposing a substrate in a process chamber of a process tool, plasma implanting a dopant species from a plasma into a portion of the substrate in the process chamber, and plasma depositing a diffusion barrier on the implanted portion of the substrate prior to removing the at least one substrate from the process tool. The diffusion barrier can be deposited in the chamber used for dopant implantation or a different chamber of the process tool.

### BRIEF DESCRIPTION OF THE DRAWINGS

For a better understanding of the present invention, reference is made to the accompanying drawings, which are incorporated herein by reference and in which:

FIG. 1 is a flowchart of an embodiment of a method for fabricating a semiconductor-based device, in accordance with one embodiment of the invention;

FIG. 2 is block diagram of a plasma-processing tool, in accordance with one embodiment of the invention;

FIG. 3 is a block diagram of a plasma-processing tool, which can be utilized as a portion of the tool of FIG. 2; and

FIG. 4 is a cross-sectional view of an embodiment of a MOSFET, in accordance with one embodiment of the invention.

### DETAILED DESCRIPTION

This invention is not limited in its application to the details of construction and the arrangement of components set forth in the following description or illustrated in the drawings. The invention is capable of other embodiments and of being practiced or of being carried out in various ways.

Also, the phraseology and terminology used herein is for the purpose of description and should not be regarded as limiting. The use of “including,” “comprising,” “having,” “containing,” “involving,” and variations thereof herein is meant to encompass the items listed thereafter and equivalents thereof as well as additional items.

The word “plasma,” is used herein in a broad sense to refer to a gas-like phase that can include any or all of electrons, atomic or molecular ions, atomic or molecular radical species (i.e., activated neutrals), and neutral atoms and molecules. A plasma typically has a net charge that is approximately zero. A plasma may be formed from one or more materials by, for example, ionizing and/or dissociating events, which in turn may be stimulated by a power source having, for example, inductive and/or capacitive coupling.

The phrase “plasma implantation” is used herein to refer to implantation techniques that utilize implantation from a plasma without the mass selection features of a traditional beam implanter. A plasma implanter typically involves both a substrate and a plasma in the same chamber. The plasma can be near to the substrate, or the substrate can be immersed in the plasma. A variety of species types from the plasma can experience implantation into the substrate. As used herein, the word “species” can refer to atoms, molecules, or collections of the same, which can be in a neutral, ionized, or excited state.

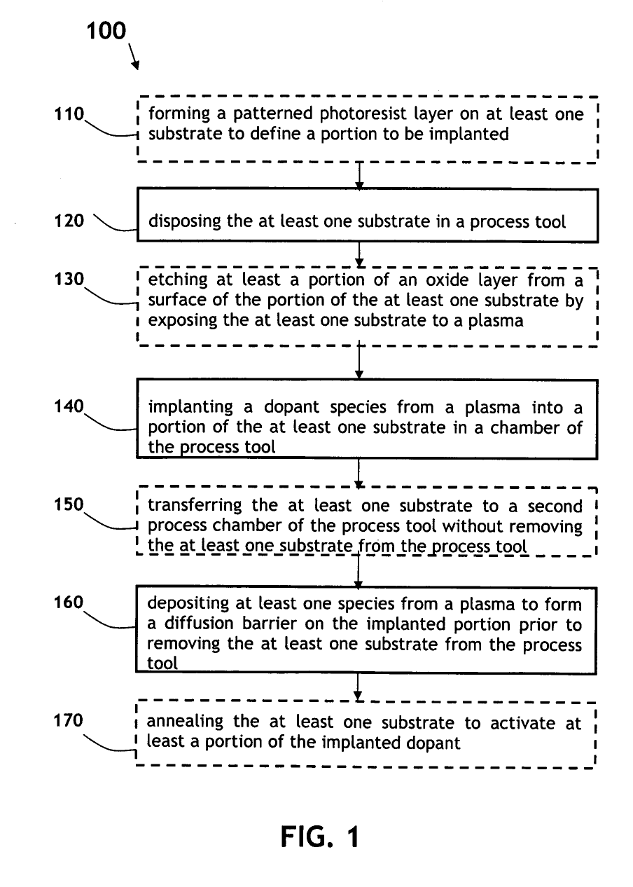

FIG. 1 is a flow diagram of an embodiment of a method 100 for fabricating a semiconductor-based device having one or more shallow junctions, according to principles of the invention. One or more substrates are provided, each including a semiconductor, such as silicon. The method 100 includes disposing 120 at least one of the substrates in a plasma processing tool that has one or more plasma processing chambers, implanting 140, from a plasma in the tool, a dopant species into a portion of the substrate, and depositing 160, from a plasma in the tool, a diffusion barrier on the implanted portion of the substrate. The method 100 can be implemented, at least in part, with, for example, a VIISta P²LAD processing system (available from Varian Semiconductor Equipment Associates, Inc. of Gloucester, Mass.)

Depositing 160 is performed without first removing the substrate from the processing tool. Thus, for example, growth of a native oxide can be avoided prior to depositing 160 the diffusion barrier. Moreover, implanting 140 and depositing 160 can be performed in the same chamber of the process tool or in different chambers of the process tool.

The method optionally includes any one or more of the following acts: forming 110 a patterned photoresist layer on the substrate to define the portion of the substrate to be implanted; etching 130 at least a portion of an oxide layer from the surface of the portion of the substrate by exposing the substrate to a plasma; transferring 150 the substrate to a second process chamber of the process tool—such as for depositing 160 the diffusion barrier—without removing the at least one substrate from the process tool; and annealing 170 the at least one substrate to activate at least a portion of the implanted dopant.

The method 100 optionally includes additional acts. For example, the method 100 can include forming 110 a patterned photoresist layer on the substrate to define the portion of the substrate surface that will receive the implant 140. The method 100 can include etching 130 a native oxide layer from the portion of the substrate to be implanted 140. Etching 130 can be provided by a plasma in any one of the one or more plasma processing chambers of the plasma processing tool. In other embodiments, etching of the oxide layer can be performed prior to the implant step externally of the plasma-processing tool. Further, the method 100 can include annealing 170 the substrate to activate the implanted dopant.

Substrates can be, for example, n-type or p-type silicon wafers. For example, as known to one having ordinary skill in the semiconductor arts, source and drain regions can be formed in an n-type silicon wafer by implanting boron at a relatively high concentration into desired portions, followed by annealing to activate at least some of the implanted dopant. As described in more detail below, a diffusion barrier can be formed before, during, and/or after implantation of the boron.

More generally, according to principles of the invention, a substrate can include a doped silicon layer. For example, the substrate can be an n-type or p-type silicon wafer, made n-type or p-type by incorporation of dopants, such as boron, phosphorus or arsenic, as known to one having ordinary skill in the semiconductor fabrication arts. The substrate can be, for example, a silicon wafer, which may incorporate buried insulating layers in the manner of, for example, a silicon-on-insulator (SOI) wafer.

The fabricated device can be, for example, a component of a circuit or a complete circuit. A component can be, for example, a diode or a transistor. A transistor can be, for example, a MOS transistor.

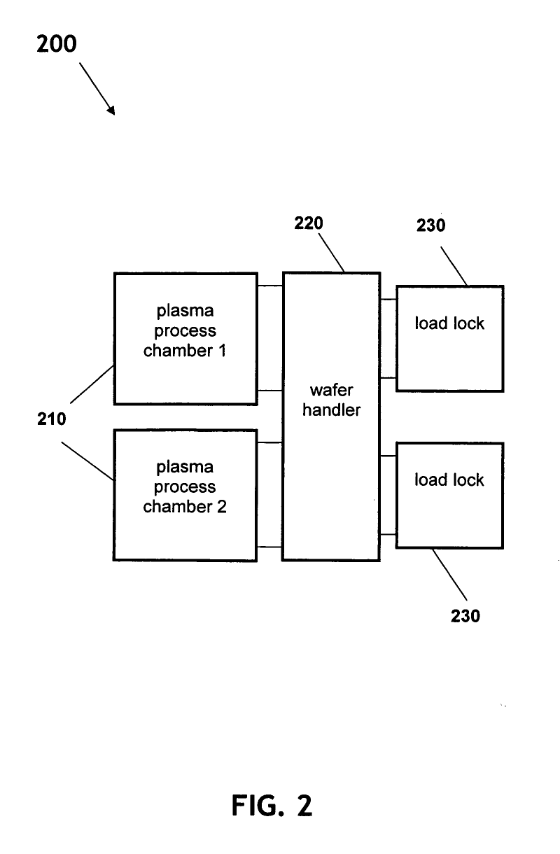

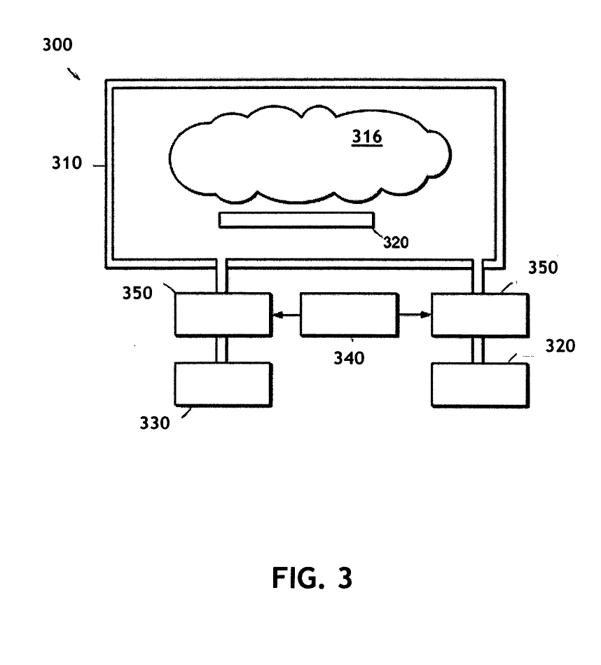

Now referring to FIGS. 2 and 3, some embodiments of process tools, which are suitable for implementation of the method 100, are described. Implanting 140 and depositing 160 can be performed in a single plasma-processing chamber of a plasma processing tool. In one alternative embodiment of the invention, implanting 140 and depositing 160 are performed in different process chambers of the tool. In such a case, the method 100 includes transferring 150 the substrate from a first plasma processing chamber of the tool, used for implanting 140, to a second plasma processing chamber of the tool, used for depositing 160.

FIG. 2 is a block diagram of a plasma-processing tool 200, in accordance with one embodiment of the invention. The plasma-processing tool 200 includes two plasma-processing chambers 210, two load locks 230, and a wafer handler 220. The wafer handler 220 supports the exchange of substrates and/or platens holding substrates between the load locks 230 and the chambers 210. The wafer handler 220 and load locks 230 can have any suitable construction, including that found in conventional handlers and load locks.

As described below, each of the chambers 210 can be used for a single or multiple types of processing. Thus, for example, one chamber 210 can be used for plasma implantation of dopant(s), and the other chamber 210 can be used for plasma deposition of a diffusion barrier. Alternatively, one chamber 210 can be used for boron implantation and the other chamber 210 can be used for arsenic implantation, to avoid cross contamination. Each chamber 210 can then also be used for other processing steps.

In one embodiment, substrates are disposed in the tool 200 after formation of a patterned photoresist layer on the substrate surfaces. Any suitable technique, including conventional techniques, can be used to form the photoresist layer. One of the chambers 210 is then used for etching of surface oxide, such as a native and/or a standard oxide. The substrates are then transferred by the wafer handler 220 to the other chamber 210 for implantation, and then returned to the first chamber 210 for deposition of a diffusion barrier. It will be apparent to one having ordinary skill that various alternative process-tool configurations are possible to improve, for example, the substrate throughput of a process tool.

For example, a process tool can include additional chambers beyond two. Because implantation can be relatively quick while layer deposition can be relatively slow, a tool can include more chambers for deposition than chambers for implantation.

In one illustrative embodiment of a process sequence, a boron-based shallow junction is formed via the following sequence of process steps:
in a plasma-processing tool, dispose silicon-based substrates having patterned photoresist and native oxide on exposed areas;
etch the native oxide by exposure to plasma with little or no applied bias (using, for example, fluorine and hydrogen-based chemistries);
evacuate etch gases, and introduce dopant gas (for example, BF₃);
plasma-implant boron, for source and drain portions, at 500V (volts) bias and a dose of 10¹⁵/cm² (approximately 10-20 seconds of exposure);
evacuate dopant gas;
form a diffusion barrier on the surface of the wafer, for example, by depositing 2-3 nm of silicon nitride using a bias of approximately 20-100V; and
remove the substrates from the plasma-processing tool.

Multiple implants can be performed, for example, to obtain primary junctions having a depth of approximately 75 nm or less, and source/drain extensions having a depth of approximately 35 nm or less. The temperature in the plasma-processing tool is preferably less than about 200° C. and more preferably less than about 100° C. to avoid substantial damage to the photoresist. As noted above, etching of the native oxide can optionally be performed before the plasma implantation step externally of the plasma-processing tool.

The silicon nitride deposition can utilize any suitable source materials. For example, the source materials can be similar to those used for plasma-enhanced chemical vapor deposition (PECVD) of silicon nitride, as known to one having ordinary skill. Such materials include, for example, silane with either ammonia or nitrogen.

In the above example, silicon nitride is deposited as the diffusion barrier. In another embodiment, nitrogen or ammonia can be reacted with silicon to form a silicon nitride diffusion barrier.

The barrier layer source materials can decompose in the plasma, and can then deposit at least some of their constituent species on a substrate surface. For example, silicon and nitrogen derived from the source materials can combine on the surface to form the silicon nitride. One embodiment utilizes a relatively low bias voltage, for example, 20V to 100V, to assist formation of the barrier layer. Moreover, the barrier layer can be deposited at a relatively low temperature, for example, room temperature, which can, for example, help to avoid destruction of a photoresist layer, if present.

An optimized barrier layer formation process can be determined by, for example, empirical means. For example, process parameter values, for parameters such as a gas mixture and/or a substrate temperature, can be varied and compared to measures of substrate quality, such as a sheet resistance and/or a junction depth of a sample substrate after annealing. Such comparisons can then indicate preferred process parameter values.

After or before removal of the substrates from the plasma-processing tool, a photoresist strip can be performed by any suitable technique. For example, photoresist can be removed via plasma ashing, which could be performed in the plasma-processing tool, and/or via wet chemistry. Subsequently, an anneal can be performed to activate implanted boron and/or other dopant species.

A junction depth can defined to coincide with the location of a boron-dopant concentration of 10¹⁸/cm³. The above-example process can provide an as-implanted junction depth of approximately 13 nm. After an activation anneal, the junction depth would be approximately 20-30 nm.

An activation anneal can be, for example, a rapid thermal anneal (RTA) having a maximum temperature of 1050° C. During an RTA, radiation is used to ramp the substrate surface temperature quickly to the maximum temperature, followed by rapid cooling. Advanced anneal techniques, such as flash anneal and laser anneal, can also be utilized. An alternative soak anneal, for example, at 1000° C. for 10-30 seconds, can be used if diffusion of the dopant is of less concern.

FIG. 3 is a cross-sectional diagram of a plasma-processing apparatus 300, in accordance with one embodiment of the invention. The apparatus 300 includes a vessel 310 associated with a chamber that can contain a plasma 316 and one or more substrates 320, which can be exposed to the plasma. The apparatus 300 also includes one or more implant-material supplies 320, one or more diffusion-barrier material supplies 330, flow controllers 350, and one or more material-supply control units 340. The plasma-processing apparatus 300 can be used to, for example, implement the method 100.

The material supplies 320, 330 supply materials to the vessel 310 for formation and maintenance of a plasma. The flow controllers 350 mediate the flow of materials from the supplies 320, 330 to control, for example, the pressure of gaseous material delivered to the vessel 310. The material-supply control unit 340 is configured to control, for example, a mixture of implant and diffusion-barrier materials supplied to the vessel 310 by communicating with the flow controllers 350. The vessel 310 can be used for plasma implantation, plasma deposition, plasma etching, and/or other fabrication-related processes. Thus, according to principles of the invention described above with respect to the method 100, the apparatus 300 can be used, for example, to both plasma dope a substrate(s) and deposit a diffusion barrier on the substrate(s). The material supplies 320, 330, flow controllers 350, and control units 340 can be of any suitable kind including those known to one having ordinary skill in the plasma-processing arts.

In the following description, exemplary embodiments of the invention that refer to particular dopants are not intended to be limiting with respect to those materials. It should be understood that principles of the invention may be applied to a broad range of implant materials and implant species. Accordingly, for simplicity, some of the described embodiments of the invention refer to a phosphorus or arsenic-doped substrate with boron introduced to create source and drain regions for a transistor. Principles of the invention can be applied, however, to a variety of materials and device structures to improve shallow-junction fabrication.

A MOS transistor, for example, may be fabricated by use of the method 100 by using, for example, a silicon substrate having a substantially uniform distribution of phosphorus dopant. The source and drain of the MOS transistor can then be formed by implanting 140 boron of a relatively high concentration into a region of the substrate. Since the boron in the source and drain regions has a higher concentration than phosphorus in those regions, the source and drain regions are converted from n-type to p-type material.

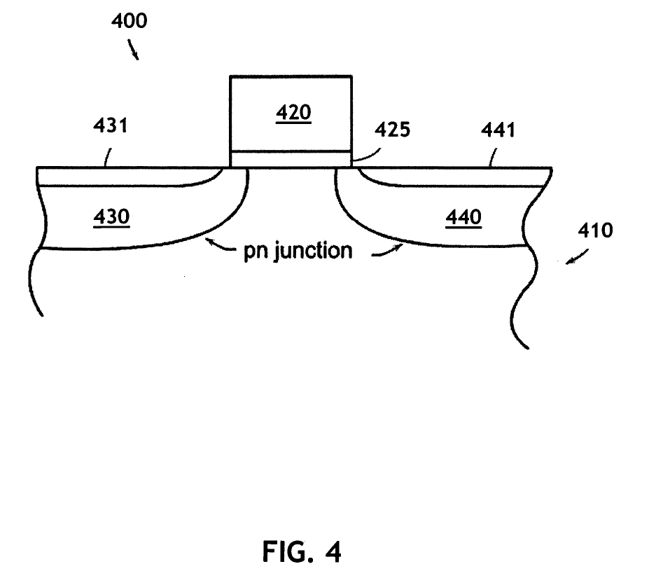

Further, n-type MOS transistors can be formed in the same (n-type) substrate by, for example, first forming a well of p-type dopant in the n-type substrate. Source and drain regions may then be formed in the well by introducing n-type dopant to define n-type source and drain regions within the p-type well. Thus, principles of the invention can be applied, for example, to improve transistors formed in wells, as well as those that require fewer doping steps during fabrication. An example of a transistor is described in more detail below with reference to FIG. 4.

Implanted dopant, for shallow-junction formation, can include one or more dopant species, and can be provided by one or more dopant materials that include the dopant species. Some suitable dopant materials include, for example, AsH₃, PH₃, BF₃, AsF₅, PF₃, B₅H₉, and B₂H₆. A carrier gas can be utilized, whether or not it provides a dopant species or a species that contributes to a diffusion barrier. Some carrier gases include He, H₂, Ne, Ar, Kr, and Xe.

Any type of suitable plasma implantation system can be utilized, including the above-described systems 200, 300. Suitable systems include those based on DC, RF and microwave power supplies, both pulsed and continuous. Power can be delivered to a plasma, in an implantation system, via, for example, capacitive coupling, inductive coupling, or a waveguide. Multiple implant steps can be used to implant 140 the dopant species and/or to deposit 160 the diffusion barrier.

Plasma implantation can be used, for example, to exploit its potential lower cost and higher throughput at lower energies. Suitable plasma implantation techniques include plasma immersion ion implantation (Pill), pulsed-plasma doping (PLAD), and other techniques. Plasma implantation can utilize, for example, a continuous or intermittent plasmas, which can be used for continuous or intermittent implantation.

In one mode of operation, the apparatus 300 utilizes an intermittent plasma. A semiconductor wafer is placed on a conductive platen that functions as a cathode, and is located in the vessel 310. An ionizable gas containing, for example, one of the above-described implant materials, is introduced into the chamber, and a voltage pulse is applied between the platen and an anode to form a glow-discharge plasma having a plasma sheath in the vicinity of the wafer. An applied voltage pulse can cause ions in the plasma to cross the plasma sheath and to be implanted into the wafer. A voltage applied between the wafer and the anode can be used to control a depth of implantation.

Plasma implantation techniques can be used to exploit their capacity to implant species in addition to dopant species. For example, a great variety of neutrals, activated neutrals, and various ions can be implanted into a substrate.

Implantation parameters can be selected to control the location and concentration level of implanted species. For example, a desired active dopant concentration of a pn junction can be achieved in part by selecting an appropriate dose amount and implantation energy. For example, an implant energy may be selected to position an implant in the underlying substrate at a location to obtain a desired junction depth. The dose can be selected to provide a desired concentration profile in the source and drain regions.

As described above, the use of plasma implantation techniques can help during fabrication of shallow junctions. Plasma implantation can provide improved dose rates at lower energies in comparison to a typical ion-beam implanter. For example, at energies under 10 keV (as typically required, for example, for shallow junction formation in sub-90 nm devices) plasma implantation can provide improved throughput for introduction of a dopant species.

FIG. 4 is a cross-sectional view of an embodiment of a MOSFET 400 having shallow junctions that can be fabricated by the method 100, utilizing, for example, one of the process tools 200, 300. The MOSFET 400 includes a silicon-based substrate 410 having a first dopant, a source region 430 and a drain region 440 defined by a second dopant, a source contact 431 in contact with the source region 430, a drain contact 441 in contact with the drain region 440, a gate contact 420 adjacent to the substrate 410, and a gate dielectric layer 425 between the gate contact 420 and the substrate 410.

The source and drain contacts 431, 441 can include silicide. The gate contact 420 can include, for example, a doped conductive polycrystalline silicon lower portion and a silicide upper portion. Alternatively, the gate contact 420 may be formed of another conductive material, such as a heavily doped semiconductor; a metal, e.g., titanium (Ti), tungsten (W), molybdenum (Mo), tantalum (Ta), or iridium (Ir); or metal compounds that provide an appropriate workfunction, e.g., titanium nitride (TiN), titanium silicon nitride (TiSiN), tungsten nitride (WN), tantalum nitride (TaN), tantalum silicide (TaSi), nickel silicide (NiSi), or iridium oxide (IrO₂).

A portion of the substrate 410 may be epitaxially grown, and the first dopant, such as phosphorus, may be incorporated into the epitaxial layer as it is grown. The source and drain contacts 431, 441 can be formed, for example, by depositing a metal layer and reacting the metal layer with the substrate 410.

The dielectric layer 425 can be formed by any suitable method including various methods conventional in the art, for example, thermal oxidation or a deposition technique. The gate dielectric 425 can be, for example, a 1 nm to 10 nm thick layer of silicon dioxide. Alternatively, the dielectric 425 can be, for example, silicon oxynitride, silicon nitride, layers of silicon nitride and silicon oxide, or a high-k dielectric. Alternative dielectric materials may be employed when, for example, a thin effective gate-oxide thickness is desired, for example, equivalent to an SiO₂ layer thickness of 2 nm or less.

The MOSFET 400, as will be understood by one having ordinary skill in the semiconductor arts, can be implemented as a NMOS or a PMOS component. The MOSFET 400 can include, for example, different doping types and levels in source, drain, and channel layer regions.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method for fabricating a semiconductor-based device, the method comprising:
disposing at least one substrate in a process chamber of a process tool;
forming a first plasma in the process chamber;
implanting a dopant species, from the first plasma, into a portion of the at least one substrate;
forming a second plasma in the process tool; and
depositing at least one species from the second plasma to form a diffusion barrier on the implanted portion of the at least one substrate prior to removing the at least one substrate from the process tool.

2. The method of claim 1, wherein the process chamber comprises a first process chamber, further comprising transferring the at least one substrate to a second process chamber of the process tool, wherein forming comprises forming the second plasma in the second process chamber.

3. The method of claim 1, wherein forming comprises forming the second plasma in the process chamber.

4. The method of claim 1, wherein implanting comprises implanting the dopant species at an implant energy selected to provide a shallow junction.

5. The method of claim 4, wherein the shallow junction has a depth of less than about 100 nm.

6. The method of claim 5, wherein the shallow junction has a depth of less than about 50 nm.

7. The method of claim 1, further comprising annealing the at least one substrate to activate at least a portion of the implanted dopant.

8. The method of claim 1, further comprising forming a patterned photoresist layer on the substrate to define the portion to be implanted, wherein depositing comprises maintaining the at least one substrate at a sufficiently low temperature to protect the photoresist layer from substantial damage.

9. The method of claim 8, wherein the temperature is less than about 200° C.

10. The method of claim 1, wherein the diffusion barrier comprises silicon nitride.

11. The method of claim 1, wherein the dopant species comprises boron.

12. The method of claim 1, further comprising forming a third plasma in the process chamber, and etching at least a portion of an oxide layer from a surface of the portion of the at least one substrate by exposing the at least one substrate to the third plasma, prior to implanting the dopant species.

13. The method of claim 1, wherein implanting comprises selecting the portion of the at least one substrate to define at least a source extension of a transistor.

14. The method of claim 1, wherein the at least one substrate comprises a semiconductor layer consisting essentially of silicon.

15. The method of claim 2, further comprising disposing at least one second substrate in the first process chamber after transferring the at least one substrate to the second process chamber, and implanting the dopant species into a portion of the at least one second substrate, while the at least one substrate is in the second process chamber.

16. The method of claim 2, further comprising disposing the at least one Is substrate in the second process chamber prior to disposing the at least one substrate in the first process chamber, forming a third plasma in the second process chamber, and etching at least a portion of an oxide layer from a surface of the portion of the at least one substrate by exposing the at least one substrate to the third plasma.

17. The method of claim 16, wherein the oxide layer comprises a native oxide.

18. The method of claim 2, further comprising disposing the at least one substrate in a third process chamber of the process tool prior to disposing the at least one substrate in the first process chamber, forming a third plasma in the third process chamber, and etching at least a portion of an oxide layer from a surface of the portion of the at least one substrate by exposing the at least one substrate to the third plasma.

19. The method of claim 1, wherein depositing comprises applying a bias voltage in a range of about 20 V to about 100V.

20. The method of claim 1, wherein depositing comprises maintaining a temperature of the at least one substrate at less than about 200° C.

21. The method of claim 1, wherein substantially no native oxide grows on the portion of the at least one substrate after implanting and before depositing.

22. The method of claim 1, further comprising etching at least a portion of an oxide layer from a surface of the portion of the at least one substrate externally of the process tool, prior to implanting the dopant species.
